(19) United States
(12) Patent Application Publication
(10) Pub. No.: US 2026/0143798 A1
(43) Pub. Date: May 21, 2026

(54) INTEGRATED CIRCUIT DEVICES INCLUDING STACKED TRANSISTORS WITH CELL- ACROSS CONTACT

(71) Applicant: Samsung Electronics Co., Ltd., Suwon-si (KR)

(72) Inventors: Young Gook Park, Rensselaer, NY (US); Hyo Jong Shin, Mechanicville, NY (US); Jinyoung Lim, Schenectady, NY (US); Kang-ill Seo, Springfield, VA (US)

(21) Appl. No.: 19/330,041

(22) Filed: Sep. 16, 2025

Related U.S. Application Data
(60) Provisional application No. 63/722,399, filed on Nov. 19, 2024.

(51) Int. Cl. H10D 84/83; H01L 23/528; H10D 30/00; H10D 30/43; H10D 62/10

(52) U.S. Cl. CPC H10D 84/832; H10D 30/43; H10D 30/502; H10D 62/121; H10W 20/427; H10W 20/435; H10W 20/43

(57) ABSTRACT

An integrated circuit device may include first and second cell structures on a substrate, a cell boundary between the first and second cell structures in a first direction, a conductive contact overlapping the cell boundary in a second direction, and a conductive track in the second cell structure. The first cell structure may include a first transistor comprising a first sidewall and a second sidewall and a second transistor comprising a third sidewall and a fourth sidewall between an upper surface of the substrate and the first transistor in the second direction. One of the third sidewall and the fourth sidewall may be between the first sidewall and the second sidewall. At least one of the first transistor and the second transistor may be electrically connected to the conductive track through the conductive contact.

### CROSS-REFERENCE TO RELATED APPLICATIONS

The present application claims the benefit of U.S. Provisional Patent Application Ser. No. 63/722,399, filed on Nov. 19, 2024, entitled CROSS-BOUNDARY SIGNAL LINE USING CELL-ACROSS CONTACT IN Z-SHAPE STACKED FET, the disclosure of which is hereby incorporated herein in its entirety by reference.

### BACKGROUND

The present disclosure generally relates to the field of integrated circuit devices and, more particularly, to integrated circuit devices including stacked transistors.

Various structures of an integrated circuit device and methods of forming the same have been proposed to increase the integration degree. For example, a stacked transistor structure including multiple transistors vertically stacked has been proposed.

The stacked transistor structure may be in an I-shape scheme or an L-shape scheme in a cross-sectional view. In the I-shape scheme, an upper transistor and a lower transistor may have (substantially) the same size (e.g., (substantially) the same cell height or (substantially) the same channel width) and may be aligned with each other in a horizontal direction. In the L-shape scheme, an upper transistor and a lower transistor may have different sizes (e.g., different cell heights or different channel widths) from each other. In the L-shape scheme, one of sidewalls of the upper transistor and one of sidewalls of the lower transistor may be aligned in a horizontal direction.

In the I-shape scheme and the L-shape scheme, a middle-of-line (MOL) structure spaced apart from the upper transistor and/or the lower transistor in a horizontal direction may be needed to provide connectivity (e.g., electrical connectivity) among front-side conductive tracks (e.g., front-side power delivery network and/or front-side signal tracks on an upper surface of the upper transistor), back-side conductive tracks (e.g., back-side power delivery network and/or back-side signal tracks on a lower surface of the lower transistor), the upper transistor, and the lower transistor because the upper transistor and the lower transistor are substantially or completely overlapped with each other in the vertical direction and may not have enough space on which the front-side conductive tracks and the back-side conductive tracks land through conductive contacts and/or conductive vias in the vertical direction. In summary, the I-shape scheme and the L-shape scheme may need extra space for the MOL structure adjacent the upper transistor and/or the lower transistor (e.g., between the transistor(s) and a cell boundary), and therefore, the overall footprint of the integrated circuit device may increase, and the integration degree of the integrated circuit device may be limited.

### SUMMARY

An aspect of the present disclosure is to provide a Z-shape scheme for a stacked transistor structure. In the Z-shape scheme, the upper transistor and the lower transistor may be staggered with respect to each other (in a horizontal direction). In other words, the upper transistor and the lower transistor in the Z-shape scheme may be positioned in a zigzag arrangement.

In the Z-shape scheme, the MOL structure may be positioned to be (completely) overlapped by the upper transistor and/or the lower transistor in the vertical direction because the upper transistor and the lower transistor have less overlap with each other in the vertical direction. In other words, the MOL structure may be provided in the spaces overlapping the upper transistor and/or the lower transistor in the vertical direction rather than in the spaces adjacent the upper transistor and/or the lower transistor. As a result, the front-side conductive tracks and back-side conductive tracks may be electrically connected to the upper transistor and the lower transistor without a detour (e.g., a detour through the areas between the transistors and a cell boundary), and the integration degree of the integrated circuit may increase.

An aspect of the present disclosure is to provide integrated circuit devices with improved flexibility and availability of the front-side conductive tracks (e.g., front-side power delivery network and/or front-side signal tracks on an upper surface of the upper transistor) and/or the back-side conductive tracks (e.g., back-side power delivery network and/or back-side signal tracks on a lower surface of the lower transistor) by utilizing a conductive contact across a cell boundary between adjacent cell structures. However, it will be understood that the embodiments, goals, and benefits of the present disclosure are not limited to the descriptions above.

An integrated circuit device, according to some embodiments, may include a substrate, a first cell structure on the substrate, a second cell structure adjacent the first cell structure on the substrate, a cell boundary between the first cell structure and the second cell structure in a first direction that is parallel with an upper surface of the substrate, a conductive contact overlapping the cell boundary in a second direction that is perpendicular to the upper surface of the substrate, and a conductive track in the second cell structure. The first cell structure may include a first transistor on the upper surface of the substrate and a second transistor between the upper surface of the substrate and the first transistor in the second direction. At least one of the first transistor and the second transistor may be electrically connected to the conductive track through the conductive contact.

An integrated circuit device, according to some embodiments, may include a substrate, a first cell structure on the substrate, a second cell structure that is bounded by the first cell structure with a cell boundary therebetween in a first direction that is parallel with an upper surface of the substrate, a conductive contact extending across the cell boundary and into the first cell structure and the second cell structure in the first direction, and a conductive track in the second cell structure. The first cell structure may include a first transistor comprising a first sidewall and a second sidewall that is opposite to the first sidewall in the first direction on the upper surface of the substrate and a second transistor comprising a third sidewall and a fourth sidewall that is opposite to the third sidewall in the first direction between the upper surface of the substrate and the first transistor in a second direction that is perpendicular to the upper surface of the substrate. The second sidewall may be between the third sidewall and the fourth sidewall in the first direction. The third sidewall may be between the first sidewall and the second sidewall in the first direction. At least one of the first transistor and the second transistor may be electrically connected to the conductive track through the conductive contact.

An integrated circuit device, according to some embodiments, may include a substrate, a first cell structure on the substrate, a second cell structure on the substrate adjacent the first cell structure, a first cell boundary between the first cell structure and the second cell structure in a first direction that is parallel with an upper surface of the substrate, a second cell boundary that is opposite to the first cell boundary with the first cell structure therebetween in the first direction, a third cell boundary that is opposite to the first cell boundary with the second cell structure therebetween in the first direction, a conductive contact extending into the first cell structure and the second cell structure in the first direction, and a conductive track extending in a second direction that is parallel with the upper surface of the substrate and is perpendicular to the first direction. The conductive track may be between the first cell boundary and the third cell boundary in the first direction. The first cell structure may include a first transistor on the upper surface of the substrate and a second transistor between the upper surface of the substrate and the first transistor in a third direction that is perpendicular to the upper surface of the substrate. The first transistor may have a first portion that is free of overlap with the second transistor in the third direction. The second transistor may have a second portion that is free of overlap with the first transistor in the third direction. The first cell structure may be electrically connected to the conductive track through the conductive contact.

### BRIEF DESCRIPTION OF THE DRAWINGS

FIGS. 1A and 1B are a plan view and a cross-sectional view of an integrated circuit device with a front-side conductive contact crossing a cell boundary according to some embodiments, respectively.

FIG. 2 is a cross-sectional view of an integrated circuit device with a back-side conductive contact crossing a cell boundary according to some embodiments.

FIG. 3 is a cross-sectional view of an integrated circuit device with a front-side conductive contact and a back-side conductive contact crossing a cell boundary according to some embodiments.

FIG. 4 is a cross-sectional view of an integrated circuit device with different numbers of front-side conductive tracks in a first cell structure and a second cell structure according to some embodiments.

FIG. 5 is a cross-sectional view of an integrated circuit device with a front-side conductive contact that is electrically connected to a front-side conductive track that is not adjacent a cell boundary according to some embodiments.

FIG. 6 is a cross-sectional view of an integrated circuit device with a shared front-side conductive track according to some embodiments.

FIG. 7 is a cross-sectional view of an integrated circuit device having more than two (2) cell structures according to some embodiments.

### DETAILED DESCRIPTION OF EMBODIMENTS

Pursuant to embodiments herein, an integrated circuit device may include a first cell structure and a second cell structure that is adjacent the first cell structure in a horizontal direction. Each of the first cell structure and the second cell structure may include an upper transistor and a lower transistor in a Z-shape scheme. For example, the upper transistor and the lower transistor may be staggered with respect to each other in the horizontal direction. In some embodiments, the upper transistor and the lower transistor may be positioned in a zigzag arrangement in the horizontal direction. The integrated circuit device may further include a conductive contact across a cell boundary between the first cell structure and the second structure in the horizontal direction.

Example embodiments will be described in greater detail with reference to the attached figures.

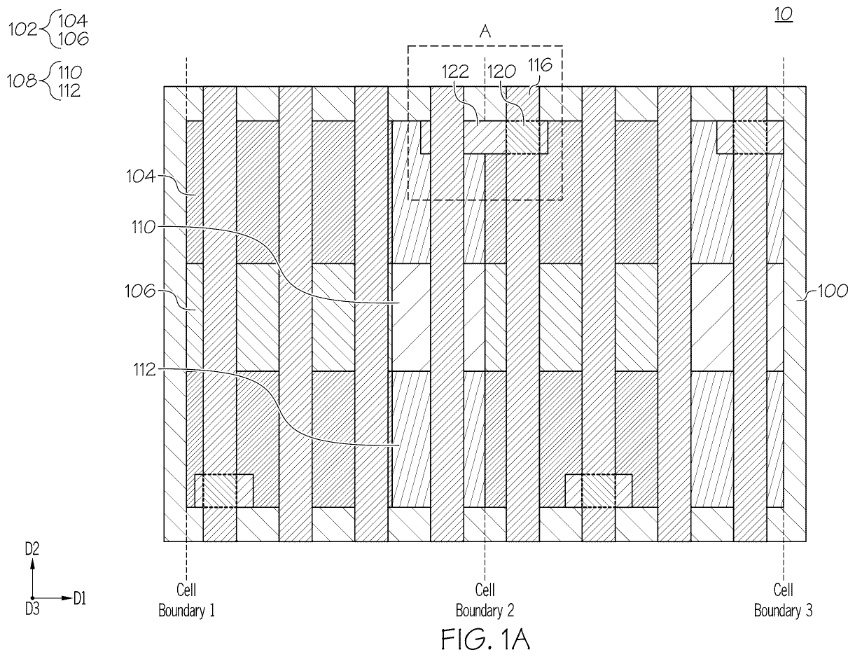

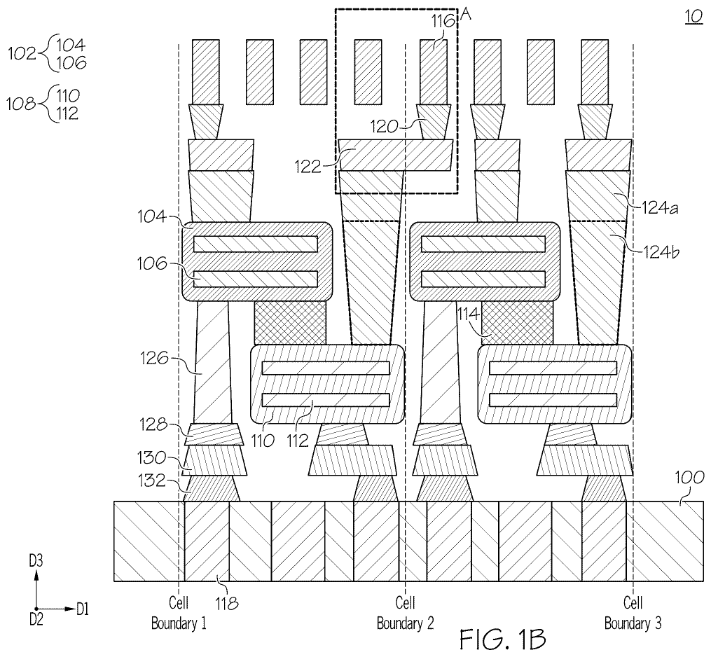

FIGS. 1A and 1B are a plan view and a cross-sectional view of an integrated circuit device 10 with a front-side conductive contact crossing a cell boundary according to some embodiments, respectively. FIG. 1A may be a plan view from an upper side of the integrated circuit device 10. For example, FIG. 1A may be a bird's eye view of the top of the integrated circuit device 10. FIG. 1B may be a cross-sectional view of the integrated circuit device 10 illustrated in FIG. 1A.

Referring to FIGS. 1A and 1B, the integrated circuit device 10 may include a first cell structure on a substrate 100. The integrated circuit device 10 may have a first cell boundary (e.g., cell boundary 1) and a second cell boundary (e.g., cell boundary 2) that is spaced apart from the first cell boundary in a horizontal direction that is parallel with an upper surface of the substrate 100. For example, the first cell boundary and the second cell boundary may be spaced apart from each other in a first direction D1 that is parallel with the upper surface of the substrate 100. The first cell structure may be between the first cell boundary and the second cell boundary in the first direction D1. The second cell boundary may be opposite to the first cell boundary with respect to the first cell structure in the first direction D1. For example, the first cell structure may refer to a region that includes various elements of the integrated circuit device 10 between the first cell boundary and the second cell boundary in the first direction D1.

The integrated circuit device 10 may include a second cell structure on the substrate 100. The second cell structure may be adjacent the first cell structure in the horizontal direction (e.g., in the first direction D1). The integrated circuit device 10 may further have a third cell boundary (e.g., cell boundary 3) that is spaced apart from the second cell boundary (e.g., cell boundary 2) in the horizontal direction (e.g., the first direction D1). For example, the second cell boundary (e.g., cell boundary 2) may be between the first cell boundary (e.g., cell boundary 1) and the third cell boundary (e.g., cell boundary 3) in the first direction D1. The second cell structure may be between the second cell boundary and the third cell boundary in the first direction D1. The third cell boundary may be opposite to the second cell boundary with respect to the second cell structure in the first direction D1. For example, the second cell structure may refer to a region that includes various elements of the integrated circuit device 10 between the second cell boundary and the third cell boundary in the first direction D1.

The substrate 100 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. In some embodiments, the substrate may be a bulk substrate (e.g., a silicon wafer), a semiconductor on insulator (SOI) substrate or an insulating layer (e.g., a monolithic insulating layer). The low-k material may have a lower dielectric constat than that of silicon oxide (e.g., SiO). The low-k material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric.

Referring to FIGS. 1A and 1B, the first cell structure of the integrated circuit device 10 may include a first transistor 102 (e.g., an upper transistor 102) and a second transistor 108 (e.g., a lower transistor 108) formed on the substrate 100. The second transistor 108 may be between (the upper surface of) the substrate 100 and the first transistor 102 in a vertical direction that is perpendicular to the upper surface and/or a lower surface of the substrate 100. Herein, the vertical direction may refer to a third direction D3 in the drawings. In some embodiments, the first transistor 102 and the second transistor 108 may be staggered in the first direction D1. For example, the center (or a central portion) of the first transistor 102 and the center (or a central portion) of the second transistor 108 may not overlap (e.g., may be misaligned with) each other in the third direction D3. For example, the center (or the central portion) of the first transistor 102 and the center (or the central portion) of the second transistor 108 may be offset from each other in the first direction D1. In some embodiments, the first transistor 102 may have a first sidewall and a second sidewall that is opposite to the first sidewall in the first direction D1, and the second transistor 108 may have a third sidewall and a fourth sidewall that is opposite to the third sidewall in the first direction D1. The first sidewall and the second sidewall of the first transistor 102 and the third sidewall and the fourth sidewall of the second transistor 108 may not overlap with each other in the third direction D3. For example, a plane of the second sidewall of the first transistor 102 may be between respective planes of the third sidewall and the fourth sidewall of the second transistor 108 in the first direction D1. A plane of the first sidewall of the first transistor 102 may be free of overlap with respective planes of the third sidewall and the fourth sidewall of the second transistor 108 in the third direction D3. For example, a plane of the third sidewall of the second transistor 108 may be between respective planes of the first sidewall and the second sidewall of the first transistor 102 in the first direction D1. A plane of the fourth sidewall of the second transistor 108 may be free of overlap with respective planes of the first sidewall and the second sidewall of the first transistor 102 in the third direction D3. In summary, the first transistor 102 may have a portion that is free of overlap with the second transistor 108 in the third direction D3, and the second transistor 108 may have a portion that is free of overlap with the first transistor 102 in the third direction D3. However, the relative locations of the first transistor 102 and the second transistor 108 are not limited to the embodiments described above. The staggered (zigzag) structure of the first transistor 102 and the second transistor 108 may be referred to as a Z-shape scheme or a Z-shape 3D stacked device (e.g., Z-shape 3D stacked field effect transistor (Z-shape 3DSFET)).

The first transistor 102 and the second transistor 108 may have different conductivity types or the same conductivity type. In some embodiments, the first transistor 102 may include a first source/drain region 104. The first transistor 102 may be a P-type transistor, and the first source/drain region 104 may be a P-type source/drain region. The second transistor 108 may include a second source/drain region 110. The second transistor 108 may be an N-type transistor, and the second source/drain region 110 may be an N-type source/drain region. However, the inventive concepts of the types of the first transistor 102 and the second transistor 108 are not limited to the embodiments described above. For example, the first transistor 102 may be an N-type transistor including an N-type source/drain region (e.g., the first source/drain region 104), and the second transistor 108 may be a P-type transistor including a P-type source/drain region (e.g., the second source/drain region 110). The first transistor 102 and the second transistor 108 may be implemented using various types of transistors (e.g., a planar transistor, a gate-all-around field-effect transistor (GAA FET), a recessed channel array transistor (RCAT), a fin field-effect transistor (FinFET), or multi-bridge-channel field effect transistor (MBCFET™)). Hereinafter, the first transistor 102 and the second transistor 108 are described as MBCFETs™ for the convenience of the description, but the types of the first transistor 102 and the second transistor 108 are not limited thereto.

The first transistor 102 may comprise first channel layers 106 (e.g., upper channel layers) and a first work function layer (e.g., an upper work function layer) (not illustrated) on the first channel layers 106. The first transistor 102 may further comprise first gate insulators (e.g., upper gate insulators) (not illustrated) on the first channel layers 106, and a first gate electrode (e.g., an upper gate electrode) (not illustrated) on the first work function layer. For example, the first gate insulators may be between the first channel layers 106 and the first work function layer. The first gate insulators, the first work function layer, and the first gate electrode may be collectively referred to as a first gate structure (e.g., an upper gate structure).

The first channel layers 106 may be spaced apart from each other in the vertical direction. In some embodiments, the first channel layers 106 may be spaced apart from each other at equal or substantially equal distance in the vertical direction. In some embodiments, each of the first channel layers 106 may have an equal or a substantially equal width in the first direction D1 and a second direction D2 that is parallel with an upper surface of the substrate and intersects the first direction D1. The second direction D2 may be perpendicular to the first direction D1. Herein, “substantially” may mean no greater than a 10% deviation. For example, when element X has a width of 10 nm and a width of element Y is substantially equal to that of element X, the width of element Y may not be less than 9 nm or greater than 11 nm.

The first gate insulators may extend around (e.g., at least partially surround) the first channel layers 106, respectively. The first work function layer may extend around (e.g., at least partially surround) the first gate insulators (and the first channel layers 106). The first gate electrode may extend around (e.g., at least partially surround) the first work function layer.

In some embodiments, the first channel layers 106 may include semiconductor material(s), for example, Si, Ge, SiGe, GaP, GaAs, SiC, SiGeC and/or InP. In some embodiments, the first gate insulators may include insulator(s), for example, silicon oxide, silicon oxynitride, silicon nitride, silicon carbonitride and/or a low-k material that has a lower dielectric constant than that of silicon oxide. In some embodiments, the first work function layer may include, for example, a TiN layer, a TaN layer, a TiAl layer, a TiC layer, a TiAlC layer, a TiAlN layer and/or a WN layer. In some embodiments, the first gate electrode may include, for example, tungsten (W), aluminum (Al) and/or copper (Cu). However, the materials of the first channel layers 106, the first gate insulators, the first work function layer, and the first gate electrode are not limited to the embodiments described above. In some embodiments, the first gate insulators and the first gate electrode may be omitted.

The second transistor 108 may comprise second channel layers 112 (e.g., lower channel layers 112) and a second work function layer (e.g., a lower work function layer) (not illustrated) on the second channel layers 112. The second transistor 108 may further comprise second gate insulators (e.g., lower gate insulators) (not illustrated) on the second channel layers 112, and a second gate electrode (e.g., a lower gate electrode) (not illustrated) on the second work function layer. For example, the second gate insulators may be between the second channel layers 112 and the second work function layer. The second gate insulators, the second work function layer, and the second gate electrode may be collectively referred to as a second gate structure (e.g., a lower gate structure).

The second channel layers 112 may be spaced apart from each other in the vertical direction. In some embodiments, the second channel layers 112 may be spaced apart from each other at equal or substantially equal distance in the vertical direction. In some embodiments, each of the second channel layers 112 may have an equal or a substantially equal width in the first direction D1 and/or the second direction D2. In some embodiments the width of the first channel layers 106 in the first direction D1 may be (substantially) the same as the width of the second channel layers 112 in the first direction D1. In some embodiments, the width of the first channel layers 106 in the second direction D2 may be (substantially) the same as the width of the second channel layers 112 in the second direction D2. However, the relative widths of the first channel layers 106 and the second channel layers 112 in the first direction D1 and the second direction D2 are not limited thereto.

The second gate insulators may extend around (e.g., at least partially surround) the second channel layers 112, respectively. The second work function layer may extend around (e.g., at least partially surround) the second gate insulators. The second gate electrode may extend around (e.g., at least partially surround) the second work function layer.

In some embodiments, the second channel layers 112 may include semiconductor material(s), for example, Si, Ge, SiGe, GaP, GaAs, SiC, SiGeC and/or InP. In some embodiments, the second gate insulators may include insulator(s), for example, silicon oxide, silicon oxynitride, silicon nitride, silicon carbonitride and/or a low-k material that has a lower dielectric constant than that of silicon oxide. In some embodiments, the second work function layer may include, for example, a TiN layer, a TaN layer, a TiAl layer, a TiC layer, a TiAlC layer, a TiAlN layer and/or a WN layer. In some embodiments, the second gate electrode may include, for example, tungsten (W), aluminum (Al) and/or copper (Cu). However, the materials of the second channel layers 112, the second gate insulators, the second work function layer, and the second gate electrode are not limited to the embodiments described above. In some embodiments, the second gate insulators and the second gate electrode may be omitted.

In some embodiments, each of the first channel layers 106 and the second channel layers 112 may be a nanosheet (that may have a thickness in a range of from 1 nm to 100 nm in the vertical direction) or may be a nanowire (that may have a circular cross-section with a diameter in a range of from 1 nm to 100 nm). The number of the first channel layers 106 and the number of the second channel layers 112 may vary.

In some embodiments the width of the first transistor 102 in the first direction D1 may be (substantially) the same as the width of the second transistor 108 in the first direction D1. In some embodiments, the width of the first transistor 102 in the second direction D2 may be (substantially) the same as the width of the second transistor 108 in the second direction D2. However, the relative widths of the first transistor 102 and the second transistor 108 in the first direction D1 and the second direction D2 are not limited thereto.

The integrated circuit device 10 may include an insulator 114 (also referred to as an inter-gate insulator 114 or a middle dielectric isolation 114) between the first transistor 102 and the second transistor 108 in the third direction D3. The insulator 114 may include insulator(s), for example, silicon nitride (e.g., SiN). However, the material of the insulator 114 is not limited thereto.

The integrated circuit device 10 may include front-side conductive tracks 116 on (the upper surface of) the first transistor 102. The front-side conductive tracks 116 may be spaced apart from each other in the first direction D1. Although not illustrated, an interlayer insulating layer may extend around (e.g., at least partially surround) the front-side conductive tracks 116. The front-side conductive tracks 116 may be spaced apart from each other by (substantially) the same distance in the first direction D1. In some embodiments, the front-side conductive tracks 116 may be spaced apart from each other by different distances in the first direction D1. In some embodiments, each of the front-side conductive tracks 116 may have the same or substantially the same width in the first direction D1. In some embodiments, one of the front-side conductive tracks 116 may have a width in the first direction D1 different from a width of another one of the front-side conductive tracks 116 in the first direction D1. In some embodiments, the distance between adjacent ones of the front-side conductive tracks 116 in the first direction D1 may be equal or substantially equal to the width of one of the front-side conductive tracks 116 in the first direction D1.

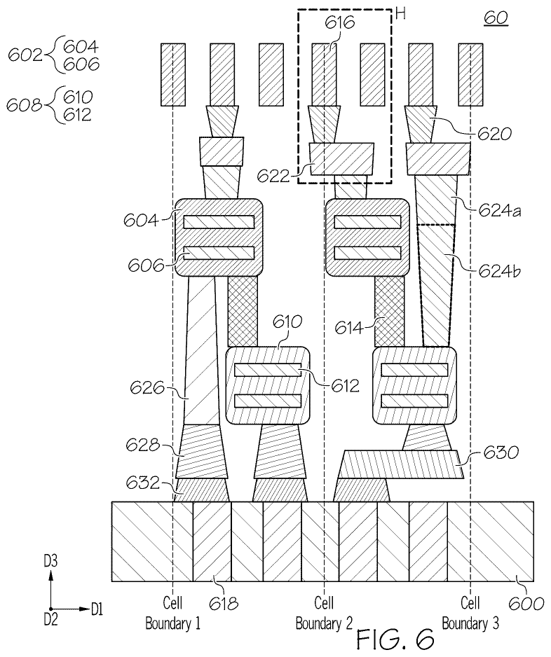

The front-side conductive tracks 116 may be within the cell structure (e.g., the first cell structure and/or the second cell structure). For example, the front-side conductive tracks 116 may be between the first cell boundary and the second cell boundary in the first direction D1. However, the embodiments of the front-side conductive tracks 116 are not limited thereto. For example, the front-side conductive tracks 116 may overlap the first cell boundary and/or the second cell boundary in the third direction D3. (will be described in detail below referring to FIG. 6). Although four (4) front-side conductive tracks 116 are illustrated between the first cell boundary and the second cell boundary in FIGS. 1A and 1B, the number of the front-side conductive tracks 116 is not limited thereto. In some embodiments, the front-side conductive tracks 116 may include a conductive material, such as a metal. For example, the front-side conductive tracks 116 may include copper, aluminum, and/or tungsten, but not limited thereto. In some embodiments, the front-side conductive tracks 116 may be configured to function as signal transfer paths (tracks) and/or a front-side power delivery network (FSPDN) for the integrated circuit device 10. For example, the front-side conductive tracks 116 may be configured to transfer a signal to or from at least one of the first transistor 102 and the second transistor 108 through a conductive contact (e.g., the front-side upper conductive contact 122, which will be described in detail below). For example, the front-side conductive tracks 116 may be configured to supply power to at least one of the first transistor 102 and the second transistor 108 through a conductive contact (e.g., the front-side upper conductive contact 122, which will be described in detail below).

The integrated circuit device 10 may include back-side conductive tracks 118 on (below)/in the substrate 100. In some embodiments, the back-side conductive tracks 118 may be in the substrate 100. In some embodiments, the back-side conductive tracks 118 may be on a lower surface of the substrate 100. For example, the integrated circuit device 10 may include back-side conductive tracks 118 on (below) the second transistor 108. Although not illustrated, an interlayer insulating layer may extend around (e.g., at least partially surround) the back-side conductive tracks 118. The back-side conductive tracks 118 may be spaced apart from each other in the first direction D1. The back-side conductive tracks 118 may be spaced apart from each other by (substantially) the same distance in the first direction D1. In some embodiments, the back-side conductive tracks 118 may be spaced apart from each other by different distances in the first direction D1. In some embodiments, each of the back-side conductive tracks 118 may have the same or substantially the same width in the first direction D1. In some embodiments, one of the back-side conductive tracks 118 may have a width in the first direction D1 different from a width of another one of the back-side conductive tracks 118 in the first direction D1. In some embodiments, the distance between adjacent ones of the back-side conductive tracks 118 in the first direction D1 may be equal or substantially equal to the width of the back-side conductive track 118 in the first direction D1.

The back-side conductive tracks 118 may be within the cell structure (e.g., the first cell structure). For example, the back-side conductive tracks 118 may be between the first cell boundary and the second cell boundary in the first direction D1. However, the embodiments of the back-side conductive tracks 118 are not limited thereto. For example, the back-side conductive tracks 118 may overlap the first cell boundary and/or the second cell boundary in the third direction D3. Although three (3) back-side conductive tracks 118 are illustrated between the first cell boundary and the second cell boundary in FIG. 1B, the number of the back-side conductive tracks 118 is not limited thereto. In some embodiments, the number of the back-side conductive tracks 118 may be the same as the number of the front-side conductive tracks 116. In some embodiments, the back-side conductive tracks 118 may include a conductive material, such as a metal. For example, the back-side conductive tracks 118 may include copper, aluminum, and/or tungsten, but not limited thereto. In some embodiments, the back-side conductive tracks 118 may be configured to perform as signal transfer paths (tracks) and/or a back-side power delivery network (BSPDN) for the integrated circuit device 10. For example, the back-side conductive tracks 118 may be configured to transfer a signal to or from at least one of the first transistor 102 and the second transistor 108 through a conductive contact (e.g., the back-side lower conductive contact 130, which will be described in detail below). For example, the back-side conductive tracks 118 may be configured to supply power to at least one of the first transistor 102 and the second transistor 108 through a conductive contact (e.g., the back-side lower conductive contact 130, which will be described in detail below).

The integrated circuit device 10 may further include a middle-of-line (MOL) structure. The MOL structure may include interlayer insulating layer(s) in which conductive wire(s) (e.g., metal wire(s)), conductive via(s) (e.g., metal via(s)), and/or conductive contact(s) (e.g., metal contact(s)) are provided. Various elements of the first transistor 102 and the second transistor 108 may be (electrically) connected to the MOL structure. In some embodiments, the front-side conductive tracks 116 and/or the back-side conductive tracks 118 may be electrically connected to the first transistor 102 and/or the second transistor 108 through the MOL structure.

Referring to FIGS. 1A and 1B, for example, the MOL structure may include front-side conductive vias 120, a front-side upper conductive contact 122, a front-side middle conductive contact 124a, a front-side lower conductive contact 124b, a back-side upper conductive contact 126, a back-side middle conductive contact 128, a back-side lower conductive contact 130, and back-side conductive vias 132. However, the MOL structure is not limited to the embodiments described above. For example, the MOL structure may include an additional element that is not described above, or some of the elements of the MOL structure described above may be omitted or integrated with each other.

In some embodiments, the front-side conductive vias 120 may be between the front-side conductive tracks 116 and a transistor (e.g., the first transistor 102 and/or the second transistor 108) in the third direction D3. The front-side upper conductive contact 122 may be between (corresponding) one of the front-side conductive vias 120 and a transistor (e.g., the first transistor 102 and/or the second transistor 108) in the third direction D3. The front-side middle conductive contact 124a may be between the front-side upper conductive contact 122 and a transistor (e.g., the first transistor 102 and/or the second transistor 108) in the third direction D3. The front-side lower conductive contact 124b may be between the front-side middle conductive contact 124a and a transistor (e.g., the first transistor 102 and/or the second transistor 108) in the third direction D3.

In some embodiments, the back-side upper conductive contact 126 may be between the back-side conductive tracks 118 and a transistor (e.g., the first transistor 102 or the second transistor 108) in the third direction D3. The back-side middle conductive contact 128 may be between the back-side upper conductive contact 126 and the back-side conductive tracks 118 in the third direction D3. The back-side lower conductive contact 130 may be between the back-side middle conductive contact 128 and the back-side conductive tracks 118 in the third direction D3. The back-side conductive vias 132 may be between the back-side lower conductive contact 130 and the back-side conductive tracks 118 in the third direction D3.

The elements of the MOL structure in the Z-shape scheme may not overlap the target transistor (e.g., the first transistor 102 or the second transistor 108) in a horizontal direction (e.g., in the first direction D1 or the second direction D2). The target transistor herein may refer to a transistor that is intended to be (electrically) connected to the elements of the MOL and/or conductive vias. Referring to FIG. 1B, for example, the front-side conductive via 120, the front-side upper conductive contact 122, and the front-side middle conductive contact 124a (electrically) connected to the first transistor 102 may not overlap the first transistor 102 in the first direction D1 or the second direction D2. Referring to FIG. 1B, for example, the front-side conductive via 120, the front-side upper conductive contact 122, the front-side middle conductive contact 124a, and the front-side lower conductive contact 124b (electrically) connected to the second transistor 108 may not overlap the second transistor 108 in the first direction D1 or the second direction D2. Referring to FIG. 1B, for example, the back-side upper conductive contact 126, the back-side middle conductive contact 128, the back-side lower conductive contact 130, and the back-side conductive via 132 electrically connected to the first transistor 102 may not overlap the first transistor 102 in the first direction D1 or the second direction D2. Referring to FIG. 1B, for example, the back-side middle conductive contact 128, the back-side lower conductive contact 130, and the back-side conductive via 132 electrically connected to the second transistor 108 may not overlap the second transistor 108 in the first direction D1 or the second direction D2. The (electrical) connection between elements of the MOL structure and the target transistor without a detour in a space between the target transistor and the adjacent cell boundary may be referred to as a direct contact scheme.

The second cell structure that is adjacent the first cell structure in a horizontal direction (e.g., the first direction D1) may comprise (substantially) the same elements of the first cell structure described above. In some embodiments, the structure and shape of the second cell structure may be (substantially) the same as those of the first cell structure. However, the embodiments of the shape of the second cell structure and the elements therein are not limited thereto. For example, some of the elements of the first cell structure described above may be modified or omitted in the second cell structure. In some embodiments, the first cell structure and the second cell structure may be a mirror-image to each other in the first direction D1. For example, the first cell structure and the second cell structure may be (substantially) symmetrical to each other with respect to the second cell boundary in the first direction D1.

Referring to region A of FIGS. 1A and 1B, the front-side upper conductive contact 122 may overlap the second cell boundary in the third direction D3. The front-side upper conductive contact 122 may across the second cell boundary and extend into the first cell structure and the second cell structure. In some embodiments, the front-side upper conductive contact 122 may be (electrically) connected to the front-side middle conductive contact 124a in the first cell structure. The front-side upper conductive contact 122 crossing the second cell boundary may be (electrically) disconnected or otherwise electrically isolated from the front-side conductive tracks 116 in the first cell structure. The front-side upper conductive contact 122 may be (electrically) connected to (one of) the front-side conductive tracks 116 in the second cell structure. The front-side upper conductive contact 122 may be (electrically) disconnected from the front-side conductive vias 120 in the first cell structure. The front-side upper conductive contact 122 may be (electrically) connected to (one of) the front-side conductive vias 120 in the second cell structure. Since the front-side middle conductive contact 124a in the first cell structure may be (electrically) connected to a transistor (e.g., the first transistor 102 and/or the second transistor 108) in the first cell structure (through the front-side lower conductive contact 124b), the transistor in the first cell structure may be (electrically) connected to the front-side conductive tracks 116 in the second cell structure through the front-side upper conductive contact 122 across the cell boundary (e.g., the second cell boundary). In some embodiments, the front-side conductive track 116 that is in the second cell structure and (electrically) connected to the front-side upper conductive contact 122 crossing the second cell boundary may be (electrically) disconnected from (a transistor (e.g., the first transistor 102 and the second transistor 108) in) the second cell structure. In summary, the front-side upper conductive contact 122 crossing the second cell boundary may (electrically) connect the elements of the MOL structure and the front-side conductive tracks 116 in the second cell structure to the elements of the MOL structure and the transistor (e.g., the first transistor 102 or the second transistor 108) in the first cell structure.

Although the front-side upper conductive contact 122 is described as extending across the second cell boundary between the first cell structure and the second cell structure, other elements of the MOL structure may extend across the second boundary to provide a connectivity between the front-side conductive tracks 116 in the second cell structure and the transistor (e.g., the first transistor 102 or the second transistor 108) in the first cell structure because, in the Z-shape scheme, the MOL structure may be positioned to be (completely) overlapped by the first transistor and/or the second transistor in the third direction D3 except the element of the MOL structure crossing the second cell boundary. Therefore, the element of the MOL crossing the second cell boundary may be formed between the first cell structure and the second structure in the first direction D1 without being interfered (e.g., blocked) by other elements of the MOL structure. As a result, the availability and usage of the conductive tracks (e.g., the front-side conductive tracks 116) may be improved (increased), while the cell height (e.g., the footprint of the cell structure) is reduced. For example, a conductive track that is located in but not used by the second cell structure may be used by the first cell structure that is adjacent the second cell structure by utilizing an element of the MOL structure crossing the cell boundary between the first cell structure and the second cell structure.

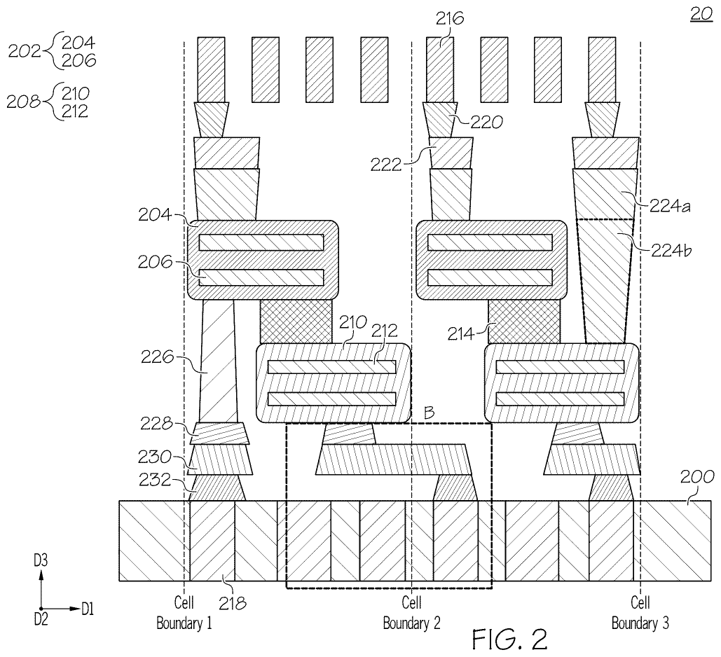

FIG. 2 is a cross-sectional view of an integrated circuit device 20 with a back-side conductive contact crossing a cell boundary according to some embodiments. Since the integrated circuit device 20 may be (at least partially) formed and configured similarly as the integrated circuit device 10 in FIGS. 1A and 1B, detailed descriptions of the common configuration with the integrated circuit device 10 may be omitted, and differences from the integrated circuit device 10 will be described in detail. The substrate 200, the first transistor 202, the first source/drain region 204, the first channel layers 206, the second transistor 208, the second source/drain region 210, the second channel layers 212, the insulator 214, the front-side conductive tracks 216, the back-side conductive tracks 218, the front-side conductive vias 220, the front-side upper conductive contact 222, the front-side middle conductive contact 224a, the front-side lower conductive contact 224b, the back-side upper conductive contact 226, the back-side middle conductive contact 228, the back-side lower conductive contact 230, and the back-side conductive vias 232 in FIG. 2 may correspond to the substrate 100, the first transistor 102, the first source/drain region 104, the first channel layers 106, the second transistor 108, the second source/drain region 110, the second channel layers 112, the insulator 114, the front-side conductive tracks 116, the back-side conductive tracks 118, the front-side conductive vias 120, the front-side upper conductive contact 122, the front-side middle conductive contact 124a, the front-side lower conductive contact 124b, the back-side upper conductive contact 126, the back-side middle conductive contact 128, the back-side lower conductive contact 130, and the back-side conductive vias 132 in FIGS. 1A and 1B, respectively.

Referring to region B of FIG. 2, at least one of the back-side lower conductive contacts 230 may extend across the second cell boundary between the first cell structure and the second cell structure in the first direction D1 to provide connectivity (e.g., electrical connectivity) between a transistor (e.g., the first transistor 202 or the second transistor 208) in the first cell structure and (one of) the back-side conductive tracks 218 in the second cell structure (through, for example, the back-side conductive via 232 in the second cell structure and the back-side middle conductive contact 228 in the first cell structure). The back-side lower conductive contact 230 crossing the second cell boundary may be (electrically) disconnected from the back-side conductive tracks 218 in the first cell structure. In some embodiments, the back-side conductive track 218 that is in the second cell structure and (electrically) connected to the back-side lower conductive contact 230 crossing the second cell boundary may be (electrically) disconnected from a transistor (e.g., the first transistor 202 and the second transistor 208) in the second cell structure.

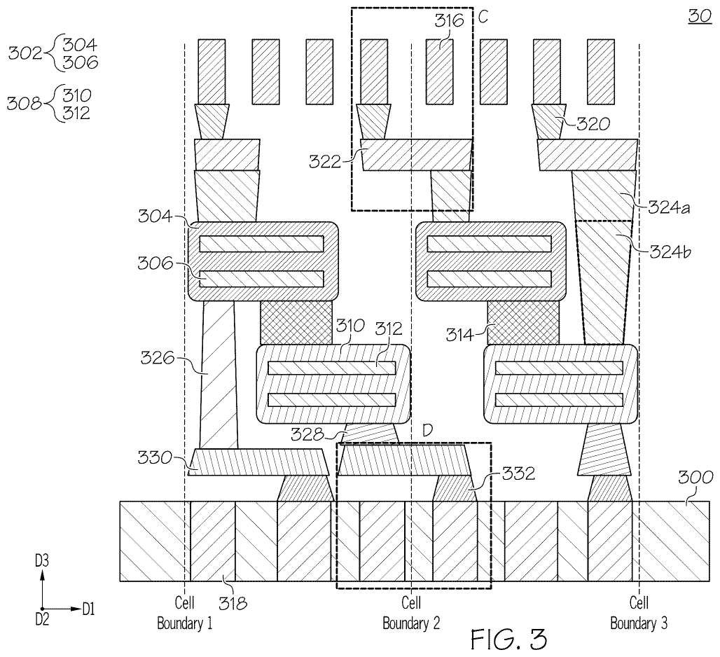

FIG. 3 is a cross-sectional view of an integrated circuit device 30 with a front-side conductive contact and a back-side conductive contact crossing a cell boundary according to some embodiments. Since the integrated circuit device 30 may be (at least partially) formed and configured similarly as the integrated circuit device 10 in FIGS. 1A and 1B and the integrated circuit device 20 in FIG. 2, detailed descriptions of the common configuration with the integrated circuit device 10 and the integrated circuit device 20 may be omitted, and differences from the integrated circuit device 10 or the integrated circuit device 20 will be described in detail. The substrate 300, the first transistor 302, the first source/drain region 304, the first channel layers 306, the second transistor 308, the second source/drain region 310, the second channel layers 312, the insulator 314, the front-side conductive tracks 316, the back-side conductive tracks 318, the front-side conductive vias 320, the front-side upper conductive contact 322, the front-side middle conductive contact 324a, the front-side lower conductive contact 324b, the back-side upper conductive contact 326, the back-side middle conductive contact 328, the back-side lower conductive contact 330, and the back-side conductive vias 332 in FIG. 3 may correspond to the substrate 100, the first transistor 102, the first source/drain region 104, the first channel layers 106, the second transistor 108, the second source/drain region 110, the second channel layers 112, the insulator 114, the front-side conductive tracks 116, the back-side conductive tracks 118, the front-side conductive vias 120, the front-side upper conductive contact 122, the front-side middle conductive contact 124a, the front-side lower conductive contact 124b, the back-side upper conductive contact 126, the back-side middle conductive contact 128, the back-side lower conductive contact 130, and the back-side conductive vias 132 in FIGS. 1A and 1B, respectively.

Region C of FIG. 3 may correspond to region A of FIGS. 1A and 1B, and region D of FIG. 3 may correspond to region B of FIG. 2. Referring to region C of FIG. 3, the front-side upper conductive contact 322 may overlap the second cell boundary in the third direction D3. The front-side upper conductive contact 322 may extend across the second cell boundary and extend into the first cell structure and the second cell structure. In some embodiments, the front-side upper conductive contact 322 may be (electrically) connected to the front-side middle conductive contact 324a in the second cell structure. The front-side upper conductive contact 322 crossing the second cell boundary may be (electrically) disconnected from the front-side conductive tracks 316 in the second cell structure. The front-side upper conductive contact 322 may be (electrically) connected to (one of) the front-side conductive tracks 316 in the first cell structure. The front-side upper conductive contact 322 may be (electrically) disconnected from the front-side conductive vias 320 in the second cell structure. The front-side upper conductive contact 322 may be (electrically) connected to (one of) the front-side conductive vias 320 in the first cell structure. Since the front-side middle conductive contact 324a in the second cell structure may be (electrically) connected to a transistor (e.g., the first transistor 302 and/or the second transistor 308) in the second cell structure, the transistor in the second cell structure may be (electrically) connected to the front-side conductive tracks 316 in the first cell structure through the front-side upper conductive contact 322 crossing the cell boundary (e.g., the second cell boundary). In some embodiments, the front-side conductive track 316 that is in the first cell structure and (electrically) connected to the front-side upper conductive contact 322 crossing the second cell boundary may be (electrically) disconnected from a transistor (e.g., the first transistor 302 and the second transistor 308) in the first cell structure. In summary, the front-side upper conductive contact 322 crossing the second cell boundary may (electrically) connect the elements of the MOL structure and the front-side conductive tracks 316 in the first cell structure to the elements of the MOL structure and the transistor (e.g., the first transistor 302 or the second transistor 308) in the second cell structure.

Referring to region D of FIG. 3, the back-side lower conductive contact 330 may overlap the second cell boundary in the third direction D3. The back-side lower conductive contact 330 may cross the second cell boundary and extend into the first cell structure and the second cell structure. In some embodiments, the back-side lower conductive contact 330 may be (electrically) connected to the back-side middle conductive contact 328 in the first cell structure. The back-side lower conductive contact 330 crossing the second cell boundary may be (electrically) disconnected from the back-side conductive tracks 318 in the first cell structure. The back-side lower conductive contact 330 may be (electrically) connected to (one of) the back-side conductive tracks 318 in the second cell structure. The back-side lower conductive contact 330 may be (electrically) disconnected from the back-side conductive vias 332 in the first cell structure. The back-side lower conductive contact 330 may be (electrically) connected to (one of) the back-side conductive vias 332 in the second cell structure. Since the back-side middle conductive contact 328 in the first cell structure may be (electrically) connected to a transistor (e.g., the first transistor 302 and/or the second transistor 308) in the first cell structure, the transistor in the first cell structure may be (electrically) connected to the back-side conductive tracks 318 in the second cell structure through the back-side lower conductive contact 330 crossing the cell boundary (e.g., the second cell boundary). In some embodiments, the back-side conductive track 318 that is in the second cell structure and (electrically) connected to the back-side lower conductive contact 330 crossing the second cell boundary may be (electrically) disconnected from a transistor (e.g., the first transistor 302 and the second transistor 308) in the second cell structure. In summary, the back-side lower conductive contact 330 crossing the second cell boundary may (electrically) connect the elements of the MOL structure and the back-side conductive tracks 318 in the second cell structure to the elements of the MOL structure and the transistor (e.g., the first transistor 302 or the second transistor 308) in the first cell structure.

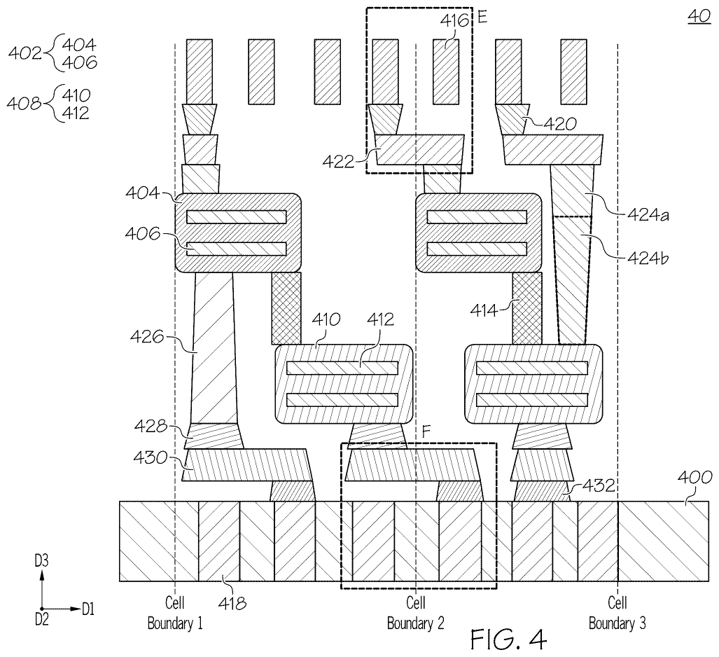

FIG. 4 is a cross-sectional view of an integrated circuit device 40 with different numbers of front-side conductive tracks in a first cell structure and a second cell structure according to some embodiments. Since the integrated circuit device 40 may be (at least partially) formed and configured similarly as the integrated circuit device 30 in FIG. 3, detailed descriptions of the common configuration with the integrated circuit device 30 may be omitted, and differences from the integrated circuit device 30 will be described in detail. The substrate 400, the first transistor 402, the first source/drain region 404, the first channel layers 406, the second transistor 408, the second source/drain region 410, the second channel layers 412, the insulator 414, the front-side conductive tracks 416, the back-side conductive tracks 418, the front-side conductive vias 420, the front-side upper conductive contact 422, the front-side middle conductive contact 424a, the front-side lower conductive contact 424b, the back-side upper conductive contact 426, the back-side middle conductive contact 428, the back-side lower conductive contact 430, and the back-side conductive vias 432 in FIG. 4 may correspond to the substrate 300, the first transistor 302, the first source/drain region 304, the first channel layers 306, the second transistor 308, the second source/drain region 310, the second channel layers 312, the insulator 314, the front-side conductive tracks 316, the back-side conductive tracks 318, the front-side conductive vias 320, the front-side upper conductive contact 322, the front-side middle conductive contact 324a, the front-side lower conductive contact 324b, the back-side upper conductive contact 326, the back-side middle conductive contact 328, the back-side lower conductive contact 330, and the back-side conductive vias 332 in FIG. 3, respectively. Region E of FIG. 4 may correspond to region C of FIG. 3, and Region F of FIG. 4 may correspond to region D of FIG. 3.

The number of the front-side conductive tracks 416 in the first cell structure and the number of the front-side conductive tracks 416 in the second cell structure may be different from each other. Although four (4) front-side conductive tracks 416 in the first cell structure and three (3) front-side conductive tracks 416 in the second cell structure are illustrated, the numbers of the front-side conductive tracks 416 in the first cell structure and the second cell structure are not limited thereto. Although not illustrated in FIG. 4, the number of the back-side conductive tracks 418 in the first cell structure may be different from the number of the back-side conductive tracks 418 in the second cell structure.

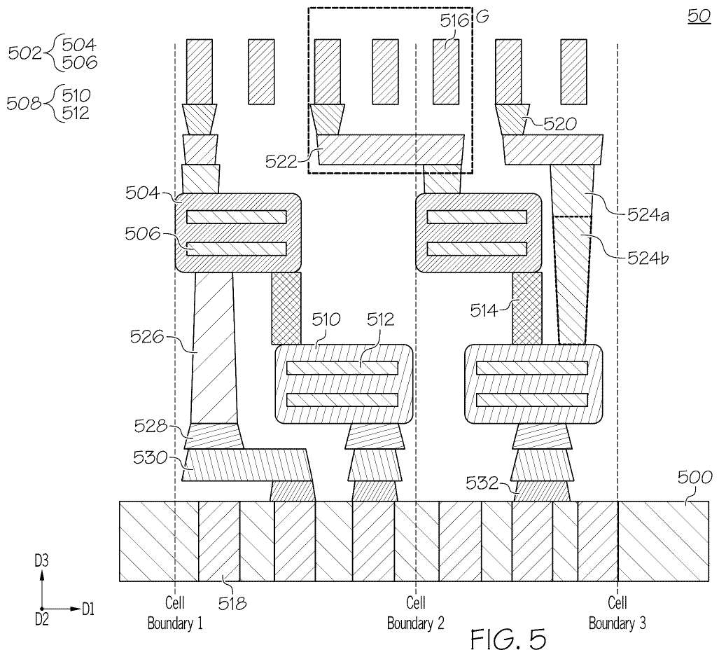

FIG. 5 is a cross-sectional view of an integrated circuit device 50 with a front-side conductive contact that is electrically connected to a front-side conductive track that is not adjacent a cell boundary according to some embodiments. Since the integrated circuit device 50 may be (at least partially) formed and configured similarly as the integrated circuit device 40 in FIG. 4, detailed descriptions of the common configuration with the integrated circuit device 40 may be omitted, and differences from the integrated circuit device 40 will be described in detail. The substrate 500, the first transistor 502, the first source/drain region 504, the first channel layers 506, the second transistor 508, the second source/drain region 510, the second channel layers 512, the insulator 514, the front-side conductive tracks 516, the back-side conductive tracks 518, the front-side conductive vias 520, the front-side upper conductive contact 522, the front-side middle conductive contact 524a, the front-side lower conductive contact 524b, the back-side upper conductive contact 526, the back-side middle conductive contact 528, the back-side lower conductive contact 530, and the back-side conductive vias 532 in FIG. 5 may correspond to the substrate 400, the first transistor 402, the first source/drain region 404, the first channel layers 406, the second transistor 408, the second source/drain region 410, the second channel layers 412, the insulator 414, the front-side conductive tracks 416, the back-side conductive tracks 418, the front-side conductive vias 420, the front-side upper conductive contact 422, the front-side middle conductive contact 424a, the front-side lower conductive contact 424b, the back-side upper conductive contact 426, the back-side middle conductive contact 428, the back-side lower conductive contact 430, and the back-side conductive vias 432 in FIG. 4, respectively. Region G of FIG. 5 may correspond to region E of FIG. 4.

Referring back to region E of FIG. 4, the front-side upper conductive contact 422 crossing the second cell boundary may (electrically) connect the first transistor 402 in the second cell structure and the front-side conductive track 416 in the first cell structure. The front-side conductive track 416 that is (electrically) connected to the front-side upper conductive contact 422 may be adjacent the second cell boundary. Unlike the embodiment described in FIG. 4, the front-side upper conductive contact 522 crossing the second cell boundary may (electrically) connect the first transistor 502 in the second cell structure and the front-side conductive track 516 that is not adjacent the second cell boundary in the first cell structure. For example, there may be an intervening front-side conductive track 516 between the connected front-side conductive track 516 and the second cell boundary.

FIG. 6 is a cross-sectional view of an integrated circuit device 60 with a shared front-side conductive track according to some embodiments. Since the integrated circuit device 60 may be (at least partially) formed and configured similarly as the integrated circuit device 40 in FIG. 4, detailed descriptions of the common configuration with the integrated circuit device 40 may be omitted, and differences from the integrated circuit device 40 will be described in detail. The substrate 600, the first transistor 602, the first source/drain region 604, the first channel layers 606, the second transistor 608, the second source/drain region 610, the second channel layers 612, the insulator 614, the front-side conductive tracks 616, the back-side conductive tracks 618, the front-side conductive vias 620, the front-side upper conductive contact 622, the front-side middle conductive contact 624a, the front-side lower conductive contact 624b, the back-side upper conductive contact 626, the back-side middle conductive contact 628, the back-side lower conductive contact 630, and the back-side conductive vias 632 in FIG. 6 may correspond to the substrate 400, the first transistor 402, the first source/drain region 404, the first channel layers 406, the second transistor 408, the second source/drain region 410, the second channel layers 412, the insulator 414, the front-side conductive tracks 416, the back-side conductive tracks 418, the front-side conductive vias 420, the front-side upper conductive contact 422, the front-side middle conductive contact 424a, the front-side lower conductive contact 424b, the back-side upper conductive contact 426, the back-side middle conductive contact 428, the back-side lower conductive contact 430, and the back-side conductive vias 432 in FIG. 4, respectively. Region H of FIG. 6 may correspond to region E of FIG. 4.

Referring to region H of FIG. 6, the front-side upper conductive contact 622 crossing the second cell boundary may (electrically) connect the first transistor 602 in the second cell structure and the front-side conductive track 616 overlapping the second cell boundary in the third direction D3. In other words, at least one of the front-side conductive tracks 616 may be between (e.g., shared by) the first cell structure and the second cell structure, and the front-side upper conductive contact 622 may be electrically connected to the at least one of the front-side conductive tracks 616 (through the corresponding front-side conductive via 620, which may overlap the second cell boundary in the third direction D3).

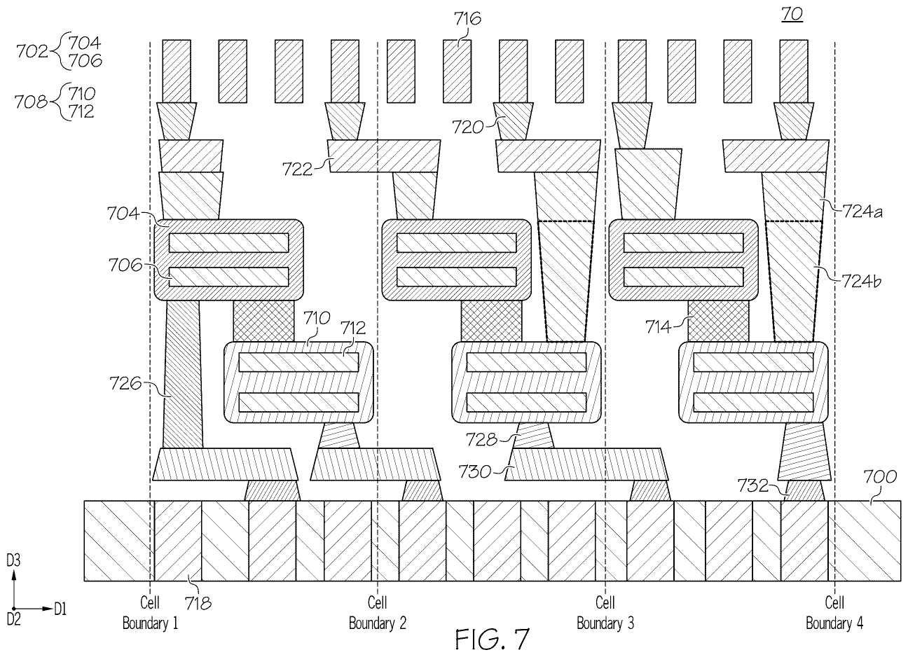

FIG. 7 is a cross-sectional view of an integrated circuit device 70 having more than two (2) cell structures according to some embodiments. Since the integrated circuit device 70 may be (at least partially) formed and configured similarly as the integrated circuit device 30 in FIG. 3, detailed descriptions of the common configuration with the integrated circuit device 30 may be omitted, and differences from the integrated circuit device 30 will be described in detail. The substrate 700, the first transistor 702, the first source/drain region 704, the first channel layers 706, the second transistor 708, the second source/drain region 710, the second channel layers 712, the insulator 714, the front-side conductive tracks 716, the back-side conductive tracks 718, the front-side conductive vias 720, the front-side upper conductive contact 722, the front-side middle conductive contact 724a, the front-side lower conductive contact 724b, the back-side upper conductive contact 726, the back-side middle conductive contact 728, the back-side lower conductive contact 730, and the back-side conductive vias 732 in FIG. 7 may correspond to the substrate 300, the first transistor 302, the first source/drain region 304, the first channel layers 306, the second transistor 308, the second source/drain region 310, the second channel layers 312, the insulator 314, the front-side conductive tracks 316, the back-side conductive tracks 318, the front-side conductive vias 320, the front-side upper conductive contact 322, the front-side middle conductive contact 324a, the front-side lower conductive contact 324b, the back-side upper conductive contact 326, the back-side middle conductive contact 328, the back-side lower conductive contact 330, and the back-side conductive vias 332 in FIG. 3, respectively.

Referring to FIG. 7, the integrated circuit device 70 may include a first cell structure between a first cell boundary (e.g., cell boundary 1 in FIG. 7) and a second cell boundary (e.g., cell boundary 2 in FIG. 7) in the first direction D1, a second cell structure between the second cell boundary and a third cell boundary (e.g., cell boundary 3 in FIG. 7) in the first direction D1, and a third cell structure between the third cell boundary and a fourth cell boundary (e.g., cell boundary 4 in FIG. 7) in the first direction D1. The second cell structure may be between the first cell structure and the third cell structure in the first direction D1. The first cell structure may be bounded by the second cell structure with the second cell boundary therebetween in the first direction D1. The second cell structure may be bounded by the third cell structure with the third cell boundary therebetween in the first direction D1.

According to FIG. 7, one of the front-side upper conductive contacts 722 may cross the second cell boundary. The front-side conductive track 716 in the first cell structure may be (electrically) connected to the first transistor 702 in the second cell structure through the front-side upper conductive contacts 722 crossing the second cell boundary. One of the back-side lower conductive contacts 730 may cross the second cell boundary. The back-side conductive track 718 in the second cell structure may be (electrically) connected to the second transistor 708 in the first cell structure through the back-side lower conductive contact 730 crossing the second boundary. One of the back-side lower conductive contacts 730 may cross the third cell boundary. The back-side conductive track 718 in the third cell structure may be (electrically) connected to the second transistor 708 in the second cell structure through the back-side lower conductive contact 730 crossing the third boundary. However, the configurations and the combinations of the elements of the MOL structures (e.g., the conductive contacts) crossing the cell boundaries are not limited to the embodiments described above. As the availability and usage of the conductive tracks are improved, the length (level) of interconnection layer of the integrated circuit device may be reduced. For example, when lower metal layers, commonly referred to as M1 layers, have improved availability and usage by utilizing the embodiments described herein, upper metal layers, commonly referred to as M2 layers, M3 layers, etc., may be reduced (e.g., omitted).

Example embodiments described herein may scale down the cell height (e.g., a footprint of a cell structure) of the integrated circuit device while improving (e.g., maximizing) the availability and usage of the conductive tracks for the signal transferring and the power delivery by utilizing the staggered transistors (Z-shape scheme), a direct contact scheme, and an element of MOL structure crossing a cell boundary between adjacent cell structures.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present inventive concepts to those skilled in the art. In the drawings, the sizes and relative sizes of layers and regions may be exaggerated for clarity. Like reference numbers may refer to like elements throughout unless clearly stated otherwise.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

As used herein, “an element A overlapping an element B in a direction X” (or similar language) means that there is at least one line that extends in the direction X and intersects both the elements A and B.

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Many different embodiments have been disclosed herein, in connection with the above description and the drawings. It will be understood that it would be unduly repetitious and obfuscating to literally describe and illustrate every combination and sub-combination of these embodiments. Accordingly, the present specification, including the drawings, shall be construed to constitute a complete written description of all combinations and sub-combinations of the embodiments described herein, and of the manner and process of making and using them, and shall support claims to any such combination or sub-combination.

The above-disclosed subject matter is to be considered illustrative, and not restrictive, and the appended claims are intended to cover all such modifications, enhancements, and other embodiments, which fall within the scope of the present inventive concepts. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a substrate;
a first cell structure on the substrate;
a second cell structure adjacent the first cell structure on the substrate;
a cell boundary between the first cell structure and the second cell structure in a first direction that is parallel with an upper surface of the substrate;
a conductive contact overlapping the cell boundary in a second direction that is perpendicular to the upper surface of the substrate; and
a conductive track in the second cell structure,
wherein the first cell structure comprises:
a first transistor on the upper surface of the substrate; and
a second transistor between the upper surface of the substrate and the first transistor in the second direction, and
wherein at least one of the first transistor and the second transistor is electrically connected to the conductive track through the conductive contact.

2. The integrated circuit device of claim 1, wherein the conductive track is farther than the first transistor from the upper surface of the substrate in the second direction, and
wherein the conductive contact is between the conductive track and the first transistor in the second direction.

3. The integrated circuit device of claim 2, wherein the conductive track is configured to supply power to the at least one of the first transistor and the second transistor through the conductive contact.

4. The integrated circuit device of claim 2, wherein the conductive track is configured to transfer a signal to or from the at least one of the first transistor and the second transistor through the conductive contact.

5. The integrated circuit device of claim 1, wherein the conductive track is in the substrate, and
wherein the conductive contact is between the upper surface of the substrate and the second transistor in the second direction.

6. The integrated circuit device of claim 5, wherein the conductive track is configured to supply power to the at least one of the first transistor and the second transistor through the conductive contact.

7. The integrated circuit device of claim 5, wherein the conductive track is configured to transfer a signal to or from the at least one of the first transistor and the second transistor through the conductive contact.

8. The integrated circuit device of claim 1, wherein the first transistor comprises a first sidewall and a second sidewall that is opposite to the first sidewall in the first direction,
wherein the second transistor comprises a third sidewall and a fourth sidewall that is opposite to the third sidewall in the first direction,
wherein one of the third sidewall and the fourth sidewall is between the first sidewall and the second sidewall in the first direction, and
wherein another one of the third sidewall and the fourth sidewall is free of overlap with the first transistor in the second direction.

9. An integrated circuit device comprising:
a substrate;
a first cell structure on the substrate;
a second cell structure that is bounded by the first cell structure with a cell boundary therebetween in a first direction that is parallel with an upper surface of the substrate;
a conductive contact extending across the cell boundary and into the first cell structure and the second cell structure in the first direction; and
a conductive track in the second cell structure,
wherein the first cell structure comprises:
a first transistor comprising a first sidewall and a second sidewall that is opposite to the first sidewall in the first direction on the upper surface of the substrate; and
a second transistor comprising a third sidewall and a fourth sidewall that is opposite to the third sidewall in the first direction between the upper surface of the substrate and the first transistor in a second direction that is perpendicular to the upper surface of the substrate,
wherein the second sidewall is between the third sidewall and the fourth sidewall in the first direction,
wherein the third sidewall is between the first sidewall and the second sidewall in the first direction, and
wherein at least one of the first transistor and the second transistor is electrically connected to the conductive track through the conductive contact.

10. The integrated circuit device of claim 9, wherein the first sidewall is free of overlap with the second transistor in the second direction, and
wherein the fourth sidewall is free of overlap with the first transistor in the second direction.

11. The integrated circuit device of claim 9, wherein the conductive track is electrically disconnected from the second cell structure.

12. The integrated circuit device of claim 11, wherein the conductive track is farther than the first transistor from the upper surface of the substrate in the second direction, and
wherein the conductive contact is between the conductive track and the first transistor in the second direction.

13. The integrated circuit device of claim 12, wherein the conductive track is configured to supply power to the at least one of the first transistor and the second transistor through the conductive contact.

14. The integrated circuit device of claim 12, wherein the conductive track is configured to transfer a signal to or from the at least one of the first transistor and the second transistor through the conductive contact.

15. The integrated circuit device of claim 11, wherein the conductive track is in the substrate, and
wherein the conductive contact is between the upper surface of the substrate and the second transistor in the second direction.

16. The integrated circuit device of claim 15, wherein the conductive track is configured to supply power to the at least one of the first transistor and the second transistor through the conductive contact.

17. The integrated circuit device of claim 15, wherein the conductive track is configured to transfer a signal to or from the at least one of the first transistor and the second transistor through the conductive contact.

18. An integrated circuit device comprising:
a substrate;
a first cell structure on the substrate;
a second cell structure on the substrate adjacent the first cell structure;
a first cell boundary between the first cell structure and the second cell structure in a first direction that is parallel with an upper surface of the substrate;
a second cell boundary that is opposite to the first cell boundary with the first cell structure therebetween in the first direction;
a third cell boundary that is opposite to the first cell boundary with the second cell structure therebetween in the first direction;
a conductive contact extending into the first cell structure and the second cell structure in the first direction; and
a conductive track extending in a second direction that is parallel with the upper surface of the substrate and is perpendicular to the first direction,
wherein the conductive track is between the first cell boundary and the third cell boundary in the first direction,
wherein the first cell structure comprises:
a first transistor on the upper surface of the substrate; and
a second transistor between the upper surface of the substrate and the first transistor in a third direction that is perpendicular to the upper surface of the substrate,
wherein the first transistor has a first portion that is free of overlap with the second transistor in the third direction,
wherein the second transistor has a second portion that is free of overlap with the first transistor in the third direction, and
wherein the first cell structure is electrically connected to the conductive track through the conductive contact.

19. The integrated circuit device of claim 18, wherein the conductive track is electrically disconnected from the second cell structure.

20. The integrated circuit device of claim 19, wherein the conductive track is electrically connected to at least one of the first transistor and the second transistor through the conductive contact.
